(19) United States
(12) Patent Application Publication
(10) Pub. No.: US 2025/0079120 A1
(43) Pub. Date: Mar. 6, 2025

(54) MULTI-CHARGED PARTICLE BEAM WRITING METHOD AND MULTI-CHARGED PARTICLE BEAM WRITING APPARATUS

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 18/805,684

(22) Filed: Aug. 15, 2024

(30) Foreign Application Priority Data
Aug. 28, 2023 (JP) 2023-138217

(51) Int. Cl. H01J 37/317; H01J 37/304

(52) U.S. Cl. CPC H01J 37/3177; H01J 37/304; H01J 2237/0437; H01J 2237/31764

(57) ABSTRACT

In one embodiment, a multi-charged particle beam writing method includes a process of grouping a multi-beam into a plurality of beam groups, a process of determining an irradiation time for each beam in each shot, and a shot division process for dividing the shot into a plurality of irradiation steps including irradiation steps with different irradiation times, grouping irradiation steps having a predetermined first irradiation time as a first group, and selecting a set of irradiation steps for which a total of irradiation times of the irradiation steps is a determined irradiation time for the beam. In the shot division process, timing of the irradiation steps in the first group of the plurality of irradiation steps belonging to each of the plurality of beam groups is determined based on a predetermined order of assignment to be different for each of the beam groups, and a number of the irradiation steps which are to be set ON.

### CROSS REFERENCE TO RELATED APPLICATION

This application is based upon and claims benefit of priority from the Japanese Patent Application No. 2023-138217, filed on Aug. 28, 2023, the entire contents of which are incorporated herein by reference.

### FIELD

the present invention relates to a multi-charged particle beam writing method and a multi-charged particle beam writing apparatus.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed. Also, in some cases, the so-called wafer direct writing method, in which a pattern is formed on the resist coated on the wafer by an electron-beam, is used.

As a form of multi-beam writing apparatus, a multi-beam writing apparatus using a blanking aperture array substrate forms multi-beam (a plurality of electron beams) by passing an electron beam emitted from e.g., an electron gun through a shaping aperture array member having a plurality of openings. The blanking aperture array substrate is provided downstream of the shaping aperture array member. The blanking aperture array substrate includes: electrode pairs (blankers) each for individually deflecting a beam in the multi-beam, and openings for beam passage each formed between an electrode pair. These electrode pairs and opening are arranged in an array form in the blanking aperture array substrate. The blanking aperture array substrate controls the electrode pairs corresponding to the beams in the multi-beam at the same potential or different potentials, thereby switching between OFF and ON of blanking deflection of the passing beam. The multi-beam formed by the shaping aperture array member passes through passage-holes between corresponding blankers of the blanking aperture array substrate. An optical column of the multi-beam writing apparatus is configured so that an electron beam deflected by a blanker is blocked, and an electron beam not deflected by a blanker is emitted on a substrate.

A writing apparatus that uses a multi-beam can emit many beams at one time, as compared to when writing is performed with a single electron beam, thus the throughput can be significantly improved. However, since the total beam current amount can be set high, deterioration of writing accuracy due to the Coulomb effect may occur. Specifically, due to repulsion between the electrons, deterioration of beam resolving power, and beam positional deviation or focus deviation on a sample surface may occur. In an optical system, the Coulomb effect occurs notably at a location where the density of electron beams is high, for example, at a cross over to which multi-beams converge, and the Coulomb effect at a cross over downstream of the blanking aperture array substrate is not constant, and varies depending on the total on-beam current amount in the multi-beam.

As a counter measure against deterioration of writing accuracy due to the Coulomb effect, for example, a technique to reduce the total on-beam current amount has been proposed (see Japanese Unexamined Patent Application Publication No. 2007-329220). This technique is effective when the standby time during which the beam cannot be set ON in a shot cycle is longer than the time during which the beam is set ON due to a reason such as slow control of beam, however, when the writing system is optimized and the standby time during which the beam cannot be set ON is reduced, the effect is smaller.

### BRIEF DESCRIPTION OF THE DRAWINGS

FIG. 1 is a schematic view of a multi-charged particle beam writing apparatus according to an embodiment of the present invention.

FIG. 2 is a plan view of a shaping aperture array member.

FIG. 3 is a cross-sectional view illustrating the configuration of a blanking aperture array substrate.

FIG. 4 is a schematic configuration diagram of a control circuit in the blanking aperture array substrate.

FIG. 5 is a configuration diagram of an I/O circuit and a cell array circuit.

FIG. 6 is a schematic configuration diagram of an individual blanking mechanism.

FIG. 7 is a diagram illustrating an example of irradiation steps in one shot cycle.

FIG. 8 is a diagram illustrating an example of beam-on timing.

FIG. 9 is a diagram illustrating an order of assignment of irradiation steps.

FIG. 10 is a diagram illustrating an example of beam-on timing.

FIG. 11 is a diagram illustrating an example of beam-on timing.

FIGS. 12A to 12C are diagrams illustrating an example of grouping of beam array.

FIG. 13 is a flowchart for explaining a writing method.

FIG. 14 is a diagram for explaining a writing operation.

FIG. 15 is a diagram illustrating an order of assignment of irradiation steps.

FIG. 16 is a diagram illustrating an example of beam-on timing.

FIG. 17 is a diagram illustrating an order of assignment of irradiation steps.

FIG. 18 is a diagram illustrating an example of beam-on timing.

FIG. 19 shows graphs illustrating an example of beam current when beam-on timing is shifted and when beam-on timing is not shifted.

### DETAILED DESCRIPTION

In one embodiment, a multi-charged particle beam writing method includes a process of emitting multi-beam of a charged particle, a process of grouping a plurality of beams included in the multi-beam into a plurality of beam groups, a process of determining an irradiation time for each beam in each shot of the multi-beam from writing pattern data, a shot division process for dividing the shot into a plurality of irradiation steps including irradiation steps with different irradiation times, grouping, as a first group, a plurality of irradiation steps, which are part of the divided plurality of irradiation steps, and have a predetermined first irradiation time, and selecting a set of irradiation steps for which a total of irradiation times of the irradiation steps is a determined irradiation time for the beam, and a process of making a shot of the multi-beam by switching between ON/OFF for each beam in the multi-beam and performing the set of the plurality of irradiation steps. In the shot division process, timing of the irradiation steps in the first group of the plurality of irradiation steps belonging to each of the plurality of beam groups is determined based on a predetermined order of assignment to be different for each of the beam groups, and a number of the irradiation steps which are to be set ON.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

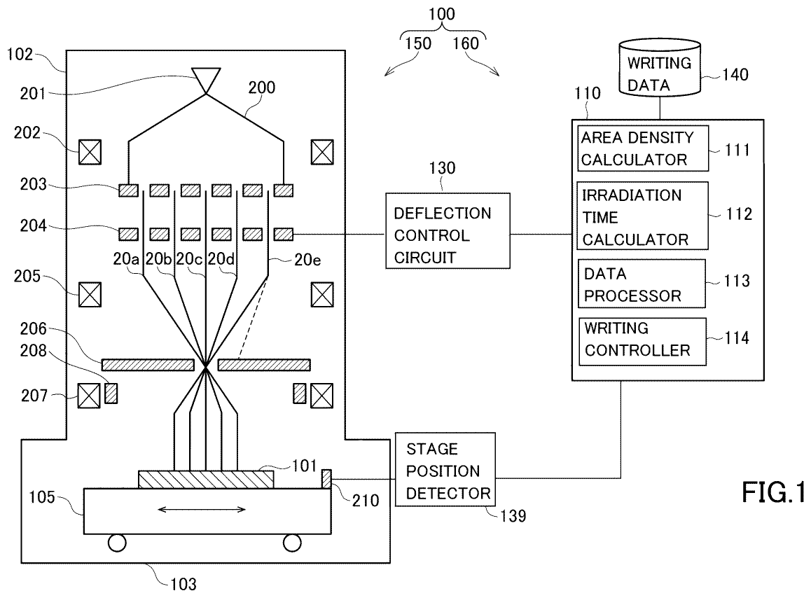

FIG. 1 is a schematic configuration diagram of a writing apparatus according to an embodiment. As illustrated in FIG. 1, a writing apparatus 100 includes a writer 150 and a controller 160. The writing apparatus 100 is an example of a multi-charged particle beam writing apparatus. The writer 150 includes an electron column 102 and a writing chamber 103. In the electron column 102, an electron gun 201, an illumination lens 202, a shaping aperture array member 203, a blanking aperture array substrate 204, a reduction lens 205, a limiting aperture member 206, an objective lens 207 and a deflector 208 are disposed.

In the writing chamber 103, an XY stage 105 is disposed. A substrate 101 as a writing target is disposed on the XY stage 105. The upper surface of the substrate 101 is coated with resist which is exposed by an electron beam. The substrate 101 is a semiconductor substrate (silicon wafer) which is fabricated to e.g., a mask blank or a semiconductor device. A stage position measurement mirror 210 is disposed on the XY stage 105.

The controller 160 includes a control computer 110, a deflection control circuit 130, a stage position detector 139, and a storage 140. Writing data is input from the outside, and stored in the storage 140. The writing data defines information on a plurality of figure patterns to be written. Specifically, for each figure pattern, the figure code, the coordinates, and the size are defined. The writing data may additionally define other information, for example, control information for irradiation amount.

The control computer 110 includes an area density calculator 111, an irradiation time calculator 112, a data processor 113 and a writing controller 114. Each component of the control computer 110 may be comprised of hardware such as an electric circuit, or software such as programs that execute these functions. Alternatively, the component may be comprised of a combination of hardware and software.

The stage position detector 139 irradiates the mirror 210 with a laser, receives reflected light from the mirror 210, and detects the position of the XY stage 105 by the laser interference method.

FIG. 2 is a conceptual diagram illustrating the configuration of the shaping aperture array member 203. The shaping aperture array member 203 is a plate-like member, and as illustrated in FIG. 2, in the surface of the shaping aperture array member 203, a plurality of openings 203a are formed in a vertical direction (y direction) and in a horizontal direction (x direction). It is preferable that the openings 203a be formed, e.g., as rectangles having the same or substantially the same dimensional shape. The openings 203a may have a circular shape.

An electron beam 200 emitted from the electron gun 201 (emitter) illuminates the shaping aperture array member 203 by the illumination lens 202. The electron beam 200 illuminates a region including all the openings 203a of the shaping aperture array member 203. Part of the electron beam 200 passes through the plurality of opening 203a of the shaping aperture array member 203, and the rest of the beam is blocked by the shaping aperture array member 203, thereby forming a plurality of electron beams, specifically, multi-beams 20a to 20e. The shape of individual multi-beam conforms with the shape of the openings 203a of the shaping aperture array member 203, thus is rectangular, for example.

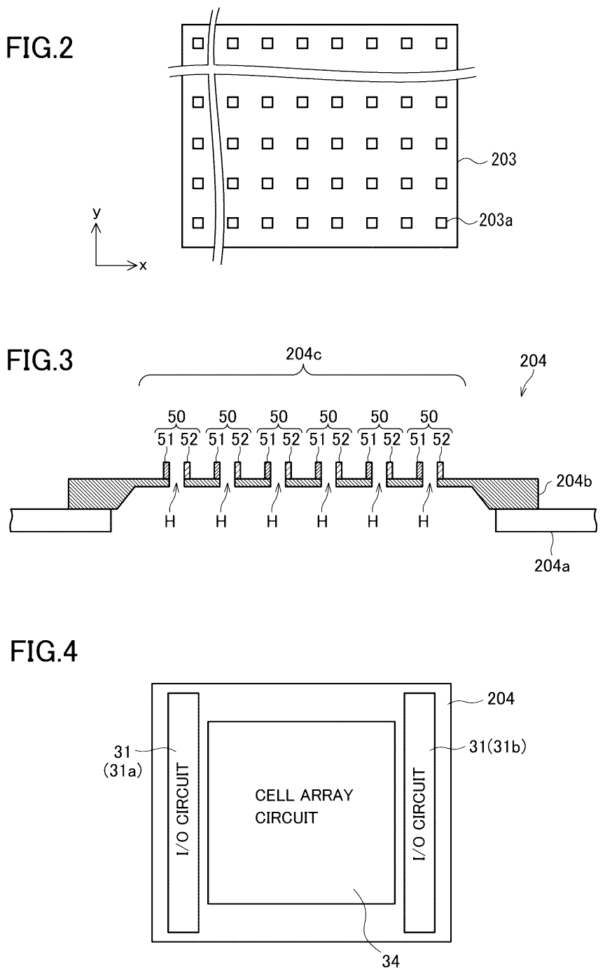

As illustrated in FIG. 3, the blanking aperture array substrate 204 includes a support stand 204a, and a semiconductor substrate 204b made of silicon provided on the support stand 204a. A central portion of the semiconductor substrate 204b is thinly scraped from the rear surface side, and is fabricated as a membrane region 204c with a thin film thickness. The periphery surrounding the membrane region 204c is an outer peripheral region with a thick film thickness, and the semiconductor substrate 204b is held on the support stand 204a by the rear surface of the outer peripheral region. A central portion of the support stand 204a is opened, and the position of the membrane region 204c is located in the region where the support stand 204a is opened.

In the membrane region 204c, a plurality of beam passage holes H are formed corresponding to the arrangement positions of the plurality of openings 203a of the shaping aperture array member 203. In each beam passage hole H, a blanker 50 is disposed, which consists of a set of two electrodes 51, 52 as a pair, and one beam in multi-beams passes through a passage hole H between an electrode pair. The blanker 50 earths one electrode 52 to maintain it at the ground potential, and switches the other electrode 51 to the ground potential or a potential other than the ground potential, thereby switching between ON/OFF of deflection of a beam passing through a passage hole H. Consequently, the blanker 50 performs blanking control to set each of multi-beams to either beam-on or beam-off state. The principle of the blanking control will be described below.

When one of the multi-beams is controlled at beam-on state, the opposed electrodes 51, 52 of the blanker 50 are controlled at the same potential, and the blanker 50 does not deflect the beam which passes through a passage hole H. When one beam is controlled at beam-off state, the opposed electrodes 51, 52 of the blanker 50 are controlled at different potentials, and the blanker 50 deflects the beam which passes through a passage hole H.

The multi-beams 20a to 20e which have passed through the blanking aperture array substrate 204 are reduced by the reduction lens 205, and travels to a central opening formed in the limiting aperture member 206.

A beam controlled at beam-off state is deflected by the blanker 50, passes a trajectory outward of the opening of the limiting aperture member 206, thus is blocked by the limiting aperture member 206. In contrast, a beam controlled at beam-on state is not deflected by the blanker 50, thus passes through the opening of the limiting aperture member 206. The trajectory of a beam is adjusted in advance by an alignment coil (not illustrated) so that a beam controlled at beam-on state is located within the opening of the limiting aperture member 206. In FIG. 1, the trajectory of the multi-beams is adjusted so that multi-beams in beam-on state converge to one point at the position of the limiting aperture member 206, and it is preferable to adjust the alignment coil so that this point is located in the central portion of the opening of the limiting aperture member 206. In this manner, ON/OFF state of each of the multi-beams is controlled by the combination of ON/OFF operation of deflection of the blanker 50 and blocking of a beam by the limiting aperture. In other words, blanking control is performed.

As described above, the blanking aperture array substrate 204 performs blanking control on each of the multi-beams 20 individually using a plurality of blankers 50. In other words, for each of the multi-beams 20, beam-on state, and beam-off state can be independently switched. In the later-described irradiation process, in a state where all beams in the multi-beams are controlled at beam-off state, only predetermined beams are blanking-controlled at beam-on state, and after a predetermined time has elapsed, all beams are controlled at beam-off state. The blanking control enables only selected beams among the multi-beams to be controlled at beam-on state for a predetermined time.

The multi-beams which have passed through the limiting aperture member 206 are focused by the objective lens 207, and form a pattern image on the substrate 101 with a desired reduction factor. Ideally, the multi-beams are arranged on the substrate 101 with the pitch which is the product of the arrangement pitch of the plurality of openings 203a of the shaping aperture array member 203 and the above-mentioned desired reduction factor. The beams (the entire beams in beam-on state among the multi-beams) which have passed through the limiting aperture member 206 are collectively deflected by the deflector 208 in the same direction, and emitted to a desired position on the substrate 101 with a focus on the surface of the substrate 101.

The irradiation of the substrate 101 with multi-beams is possible even when the XY stage 105 is in a still state or is continuously moved. When the XY stage 105 is continuously moved, the amount of change in the stage position is measured by the stage position detector 139, and using the measurement result, the position of the multi-beams is continuously changed using the deflector 208 so as to follow the movement of the XY stage 105. This is called stage tracking deflection. The position of the multi-beams on the substrate 101 can be fixed by the stage tracking deflection. At least when the substrate 101 is irradiated with a beam, stage tracking deflection is performed so that the position of each beam in the multi-beams on the substrate 101 is controlled to be fixed.

The blanking aperture array substrate 204 includes a control circuit to apply a desired voltage to the blankers 50 in addition to the blankers 50 and the passage holes H described earlier. As illustrated in FIG. 4, the control circuit includes an I/O circuit 31 and a cell array circuit 34.

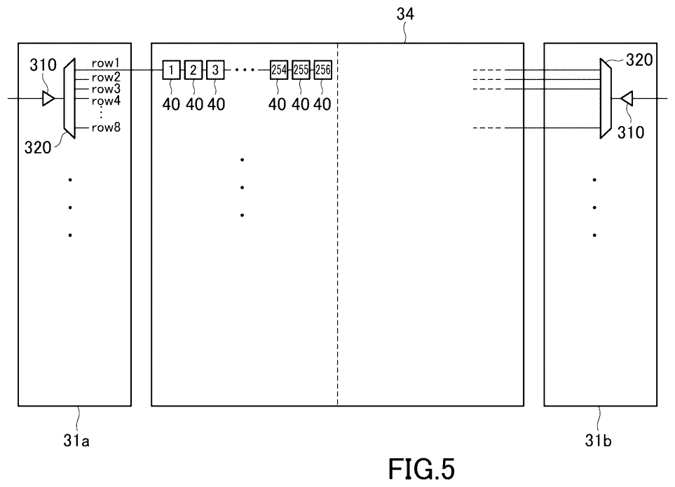

As illustrated in FIG. 5, the cell array circuit 34 is provided with a plurality of cells that form individual blanking mechanisms 40 each for driving a blanker 50. FIG. 5 illustrates an example of a blanking aperture array substrate having 262,144 cell array circuits in 512 rows and 512 columns, and blankers. One individual blanking mechanism 40 drives one blanker 50. The I/O circuit 31 outputs the data received from the deflection control circuit 130 to the cell array circuit 34. For example, the I/O circuit 31 includes an I/O circuit 31a disposed on one side of the cell array circuit 34 and configured to output data to the individual blanking mechanism 40; and an I/O circuit 31b disposed on the other side of the cell array circuit 34 and configured to output data to the individual blanking mechanism 40.

The I/O circuit 31 is provided with a plurality of selectors 320 (demultiplexers). Each selector 320 receives via an amplifier 310 irradiation time control data that defines ON/OFF of each beam, and outputs the irradiation time control data from a corresponding output line. Each output line is connected in series to a plurality of individual blanking mechanisms 40.

The selector 320 has, for example, eight output lines row1 to row8, and each output line is connected to 256 individual blanking mechanisms 40. Providing each of the I/O circuits 31a, 31b with 64 selectors 320 makes it possible to transfer the irradiation time control data to 512×512 individual blanking mechanisms 40 that constitute the cell array circuit 34.

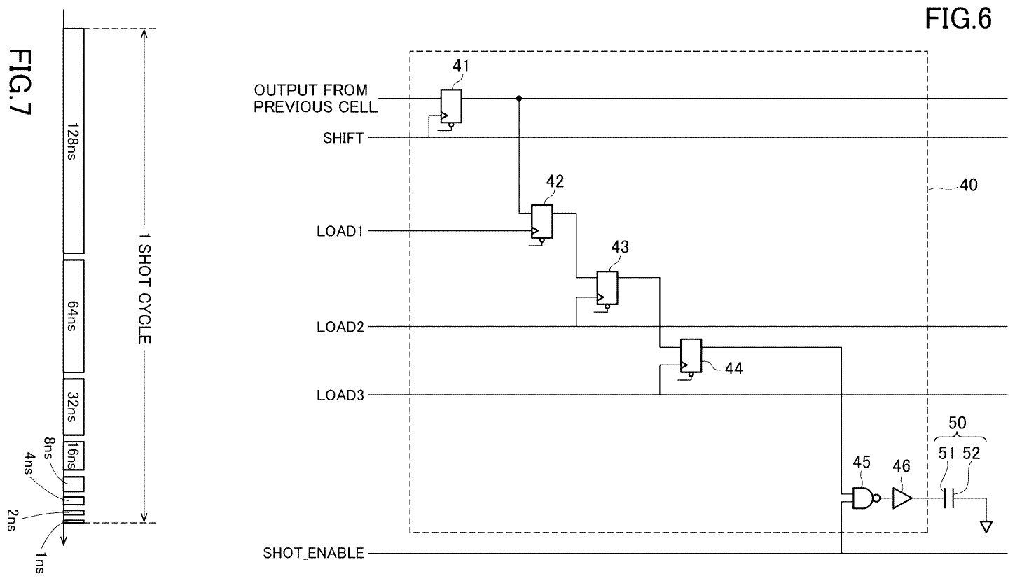

As illustrated in FIG. 6, the individual blanking mechanism 40 includes a shift register 41, a pre-buffer 42, a buffer 43, a data register 44, a NAND circuit 45 and an amplifier 46. The shift register 41 transfers the data output from the shift register of the previous stage cell to the shift register of the subsequent stage cell in accordance with a clock signal (SHIFT).

The pre-buffer 42 stores irradiation time control data for the cell use in accordance with a clock signal (LOAD1), the irradiation time control data being output from the shift register 41.

The buffer 43 fetches and holds the output value of the pre-buffer 42 in accordance with a clock signal (LOAD2).

The data register 44 fetches and holds the output value of the buffer 43 in accordance with a clock signal (LOAD3).

The output signal of the data register 44, and shot enable signal (SHOT_ENABLE) are input to the NAND circuit 45. The output signal of the NAND circuit 45 is provided to an electrode 51 of the blanker 50 via the amplifier 46 (driver amplifier).

When the output signal of the data register 44 and the shot enable signal are both High, the output of NAND circuit 45 becomes Low, the electrode 51 and the electrode 52 have the same potential, and the blanker 50 does not deflect a beam, thus the beam is set ON. When at least one of the output signal of the data register 44 and the shot enable signal is Low, the output of NAND circuit 45 becomes High, the electrode 51 and the electrode 52 have different potentials, and the blanker 50 deflects a beam, thus the beam is set OFF.

The shot enable signal is input to the NAND circuits 45 of all individual blanking mechanisms 40, thus all beams can be set OFF by setting the shot enable signal to Low regardless of the output signal of the data register 44.

With the shot enable signal maintained at High, ON/OFF of the beam is switched by the output of the data register 44. Specifically, when the irradiation time control data indicates 1 (High), the beam is set ON, and when the irradiation time control data indicates 0 (Low), the beam is set OFF.

In order to form a resist pattern having desired dimensions by exposure of the resist, it is necessary to control the irradiation amount at an appropriate value. In other words, in the blanking control, not only the ON/OFF of the beam is switched, but also the time when the beam is set ON needs to be controlled. The blanking control is performed by a logic circuit, that is, a digital circuit, thus the irradiation time is expressed in terms of integer value. For example, an irradiation time T is divided by a quantization unit Δ to calculate a gradation irradiation time N. Although the quantization unit Δ can be set variously, the quantization unit Δ is set so that the maximum irradiation time obtained by multiplying the maximum value of the gradation irradiation time N by the quantization unit Δ is greater than the maximum value of irradiation time necessary for exposure. The quantization unit Δ is set to, e.g., 1 ns.

In the multi-beam writing, some beams among the multi-beams are positioned to the inside of a pattern, and other beams are positioned to the end of the pattern or a region where there is no pattern, thus the irradiation time control data assigned to each beam in the multi-beams is not the same for all beams. Therefore, it is necessary to independently control the irradiation time of each beam in the multi-beams. As a form of such control, one shot is divided into multiple irradiation steps with different lengths using the circuit of a blanking plate 204 illustrated in FIG. 4, and control is performed so that only in the irradiation steps needed to obtain a desired exposure time for each beam, the beam is set ON. Thus, a gradation value N is converted to a binary number with n digits, and the length of an irradiation step corresponding to each digit of the binary number of n digits, in other words, the time when the beam is ON is set to the time obtained by multiplying a decimal number corresponding to each digit of the binary number by Δ.

For example, when the gradation irradiation time N=50, and the number of digits n=8, from the relationship of 50=2⁵+2⁴+2¹ in which a decimal number is expressed by the sum of power of 2, the irradiation time control data is uniquely determined as “00110010”. Similarly, when the gradation irradiation time N=100, and the number of digits n=8, the irradiation time control data is “01100100”.

The first digit from the lowest place of the irradiation time control data corresponds to an irradiation step with an irradiation time of 1Δ. The second digit from the lowest place of the irradiation time control data corresponds to an irradiation step with an irradiation time of 2Δ. The third digit from the lowest place of the irradiation time control data corresponds to an irradiation step with an irradiation time of 4Δ. The fourth digit from the lowest place of the irradiation time control data corresponds to an irradiation step with an irradiation time of 8Δ. The fifth digit from the lowest place of the irradiation time control data corresponds to an irradiation step with an irradiation time of 16Δ. The sixth digit from the lowest place of the irradiation time control data corresponds to an irradiation step with an irradiation time of 32Δ. The seventh digit from the lowest place of the irradiation time control data corresponds to an irradiation step with an irradiation time of 64Δ. The eighth digit from the lowest place of the irradiation time control data corresponds to an irradiation step with an irradiation time of 128Δ. In other words, one shot is divided into irradiation steps that is the same in number as the number of digits (the number of bits) n of the irradiation time control data, and each irradiation step has an irradiation time of

$$Δ \times {2}^{k - 1} ( k = 1 , 2 , … , n ) .$$

FIG. 7 illustrates an example of irradiation steps for one shot when the number of digits n=8, the quantization unit Δ=1 ns. In this example, each irradiation step is performed in descending order of irradiation time. The first irradiation step is irradiation with an irradiation time of 128 ns. The second irradiation step is irradiation with an irradiation time of 64 ns. The third irradiation step is irradiation with an irradiation time of 32 ns. The fourth irradiation step is irradiation with an irradiation time of 16 ns. The fifth irradiation step is irradiation with an irradiation time of 8 ns. The sixth irradiation step is irradiation with an irradiation time of 4 ns. The seventh irradiation step is irradiation with an irradiation time of 2 ns. The eighth irradiation step is irradiation with an irradiation time of 1 ns. Note that even if the irradiation steps are replaced, the total irradiation time does not change, thus the irradiation steps may be performed in an order different from the order in FIG. 7.

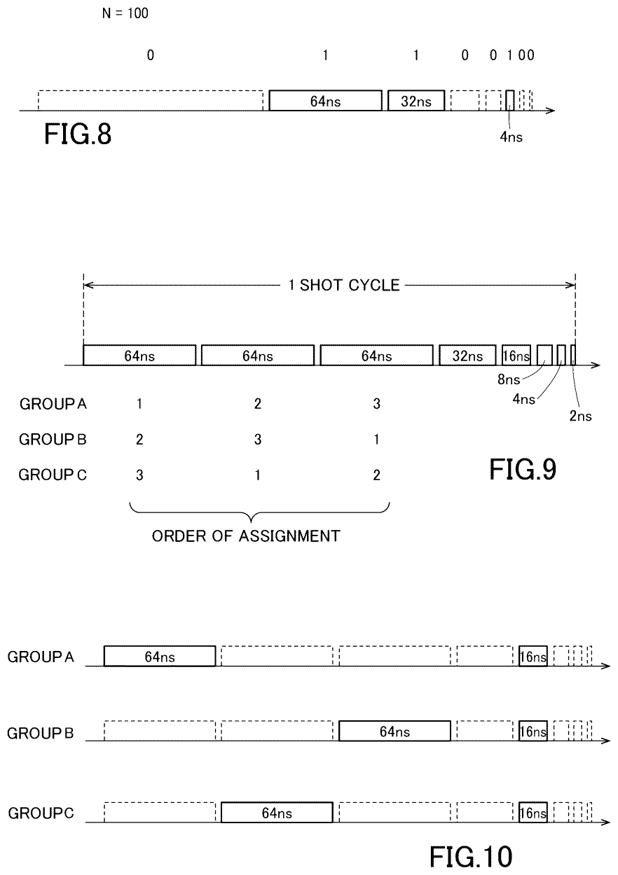

When N=100, the irradiation time control data is “01100100”, and as illustrated in FIG. 8, the beam is controlled ON by the second (64 ns), the third (32 ns), and the sixth (4 ns) irradiation steps, and the beam is controlled OFF by the first, fourth, fifth, seventh, and eighth irradiation steps.

As described earlier, a necessary irradiation time is set for each beam in the multi-beams. In a shot, even when e.g., N=100 is set as the gradation irradiation time for a beam, a different gradation irradiation time for another beam, e.g., N=50 may be set. Although multiple irradiation processes in one shot cycle are performed simultaneously for all multi-beams, in each irradiation process, the beam is independently controlled at beam-on or beam-off. Specifically, for the beam of the gradation irradiation time N=100, and the beam of N=50, beam-on, and beam-off in each irradiation process are controlled by different irradiation time data, in other words, controlled by different combinations of beam-on, and beam-off corresponding to each irradiation process. In this manner, the irradiation time of each beam in the multi-beams in one shot cycle is independently controlled for the beam.

In writing by electron beam irradiation, when a pattern is irradiated with a uniform irradiation amount, so-called proximity effect problem arises in that pattern dimensions increase where the density of pattern is high. This is because electrons which have passed through the resist applied to the upper surface of the substrate as a writing target are backscattered by the substrate, and are incident again to the resist causing second resist exposure. In order to correct the proximity effect, a method for correcting the irradiation amount is used based on the pattern density in the periphery of the beam irradiation position.

In this method, the irradiation amount is reduced for a higher pattern density so that the amount of exposure of the resist, in other words, the sum of the primary amount of exposure by irradiation, and the secondary amount of exposure by backscattering is constant regardless of the pattern density. As a result, the pattern dimensions can be made constant regardless of the pattern density. The secondary amount of exposure by backscattering is approximately half the primary amount of exposure by irradiation, and in this case, a pattern with a density of 100% uses half the irradiation amount for a pattern with a density of 0%. Proximity effect correction irradiation amount D is given, for example, by the following Expression.

$$D = {D}_{base} \times \frac{0.5 + η}{0.5 + η U}$$

Where D_{base} is a reference irradiation amount, η is a backscatter coefficient, and U is an average pattern density at the irradiation position.

In multi-beam writing, particularly, in multi-beam writing using a large number of multi-beams, both a region with a high density and a region with a low density may be present in the region where multi-beam writing is performed. Therefore, in order to make it possible to perform writing even when a region with zero density is always present, in other words, a region is present in which the irradiation time after correction of the proximity effect is the longest, the maximum time of shot and the cycle time for a shot need to set longer than the irradiation time after correction of the proximity effect of a region with zero density. In addition, in order to simplify the control, a stage speed is calculated which allows writing to be performed with the shot cycle time in a region with zero density, and it is often the case that the stage speed is fixed to the calculated stage speed, so-called stage constant speed traveling is used.

As a result, the multi-beams for exposing a region with a low pattern density are almost in beam-on state in the shot cycle, however, the multi-beams for exposing a region with a high pattern density, part in the shot cycle, particularly, the multi-beams for exposing a region with 100% pattern density are beam-on state for approximately half the time of the shot cycle, and are controlled at off state for the remaining time.

The feature of the multi-beam writing apparatus is that the total amount of current of the multi-beams is increased by using a large number of beams so that low sensitivity resist can be written at a high speed. On the other hand, a fundamental problem arises that when the total amount of current of the multi-beams is increased, the beam resolving power and the resolution of a writing pattern deteriorate due to the Coulomb effect. In this embodiment, in order to reduce the writing accuracy deterioration due to the Coulomb effect without lowering the writing speed, control is performed so that the ON timing of each beam in the multi-beams in the shot cycle is shifted. As described above, the beam-on time in the shot cycle is short in a region with a high proximity effect density, and one shot is performed in multiple irradiation steps, thus blanking control on the multi-beams is performed so as to reduce the total amount of current of the multi-beams in ON state without significantly expanding the shot cycle or significantly lowering the writing speed.

In this embodiment, in one shot cycle, multiple (m) irradiation steps with an irradiation time of T1, and multiple irradiation steps with an irradiation time less than T1 are provided. When the irradiation time for each irradiation step is proportional to power of 2, irradiation time control is simple and preferred, thus an example in this case will be described. The irradiation steps with an irradiation time less than T1 have different irradiation times. The multi-beams are grouped into m groups, and in each group, the order of assignment of the irradiation steps with an irradiation time of T1 is changed, and irradiation is performed according to the order of assignment. Group information indicating each beam belongs to which group is stored in the storage 140.

Such irradiation steps can be generated by dividing some irradiation steps in sets of multiple irradiation steps with an irradiation time of power of 2. For example, the first irradiation step with an irradiation time of 128 ns in the multiple irradiation steps illustrated in FIG. 7 is divided into two irradiation steps with an irradiation time of 64 ns. Although the number of irradiation steps increases due to the division, in order to prevent reduction in the writing speed, it is preferable that the irradiation step having the shortest irradiation time (irradiation time of 1 ns) be deleted so as not to increase the number of digits (the number of bits) of the irradiation time control data. Thus, as illustrated in FIG. 9, the first to third irradiation steps is irradiation for 64 ns. The fourth irradiation step is irradiation for 32 ns. The fifth irradiation step is irradiation for 16 ns. The sixth irradiation step is irradiation for 8 ns. The seventh irradiation step is irradiation for 4 ns. The eighth irradiation step is irradiation for 2 ns. Since the irradiation step having the shortest irradiation time (irradiation time of 1 ns) is deleted, the quantization unit Δ can be set to 2 ns which is two times 1 ns.

In addition, in order to shift ON timing of the multi-beams, the multi-beams are classified into multiple groups, and blanking control is performed for each group by a different method. For instance, in the example of FIG. 9, the multi-beams are classified into three groups A to C, and for the beam in group A, the order of assignment of the first irradiation step is 1st, the order of assignment of the second irradiation step is 2nd, and the order of assignment of the third irradiation step is 3rd. For the beam in group B, the order of assignment of the third irradiation step is 1st, the order of assignment of the first irradiation step is 2nd, and the order of assignment of the second irradiation step is 3rd. For the beam in group C, the order of assignment of the second irradiation step is 1st, the order of assignment of the third irradiation step is 2nd, and the order of assignment of the first irradiation step is 3rd.

For example, when the irradiation time for one shot is 80 ns, the gradation irradiation time is 40 because the quantization unit is 2 ns. From the relationship of 40=2⁵+2³ in which a decimal number is expressed by the sum of power of 2, when exposure is performed in FIG. 9 in one of three irradiation steps with an irradiation time of 64 ns, and in the irradiation step with an irradiation time of 16 ns, a desired exposure time of 80 ns is obtained. When the order of assignment as described above is set, as illustrated in FIG. 10, the beam in group A is set ON in the first irradiation step and in the fifth irradiation step. The beam in group B is set ON in the third irradiation step and in the fifth irradiation step. The beam in group C is set ON in the second irradiation step and in the fifth irradiation step. The beam in groups A to C is set ON at a different timing in the irradiation steps with an irradiation time of 64 ns, thus the amount of current of on-beam can be reduced.

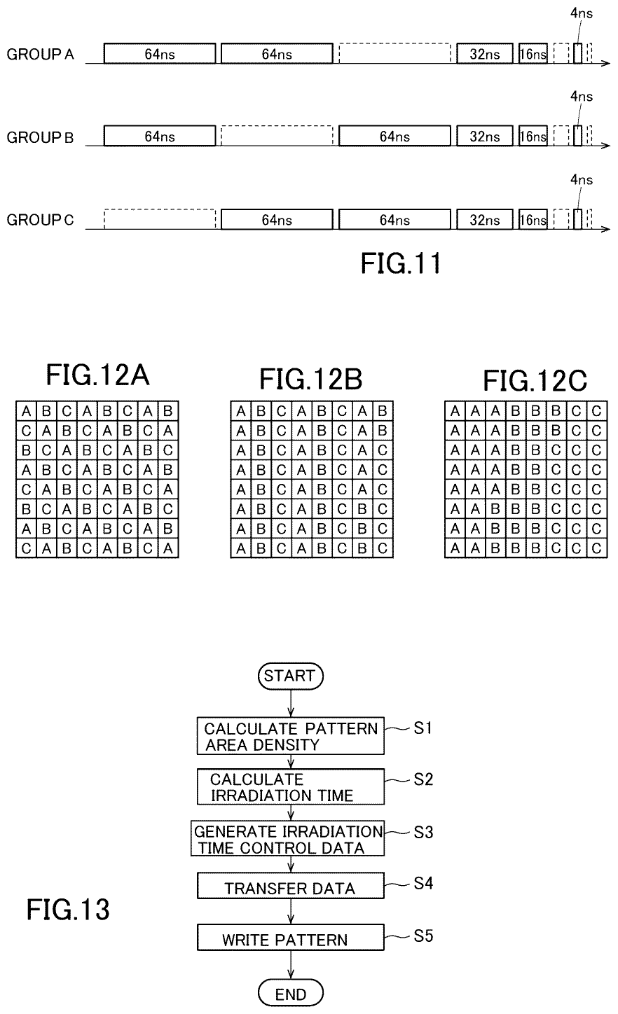

For example, when the irradiation time for one shot is 180 ns, the gradation irradiation time is 90 because the quantization unit is 2 ns. From the relationship of 90=2⁶+2⁴+2³+2¹, in one shot cycle, the beam is set ON in two of three irradiation steps with an irradiation time of 64 ns in FIG. 9, and in the irradiation steps with an irradiation time of 32 ns, 16 ns and 4 ns. When the order of assignment as described above is set, as illustrated in FIG. 11, the beam in group A is set ON in the first, second, fourth, fifth and seventh irradiation steps. The beam in group B is set ON in the first, third, fourth, fifth and seventh irradiation steps. The beam in group C is set ON in the second, third, fourth, fifth and seventh irradiation steps. Regarding the irradiation steps with an irradiation time of 64 ns, two groups are simultaneously ON, but three groups are not simultaneously ON, thus the amount of current of on-beam can be reduced.

Specifically, when all beams in the multi-beams perform irradiation for an irradiation time of 180 ns, all current of averaged on-beam in the shot cycle can be reduced to the standard of the average value of the number of beams which are ON in each irradiation step with a weight of the irradiation time of each irradiation step, (64×2+64×2+64×2+32×3+16×3+4×3)/(64+64+64+32+16+4)/3=73%. In the example of FIG. 11, when the irradiation time after correction of the proximity effect of a region with pattern density 0 is set to 250 ns, the irradiation time of a region with pattern density 40% is approximately 180 ns. In other words, the pattern density is high in a region with a pattern density of 40% or more, thus the number of multi-beams controlled by beam-on, and the current amount of multi-beams controlled by ON are large, however, in this embodiment, the average value of all current of the on-beam in the shot cycle can be reduced by 30%.

In this manner, the order of assignment of irradiation steps is set differently for each group so that the ON timing of the multi-beams is shifted between groups, and the average value of the total current of the on-beam in the multi-beams in the shot cycle can be decreased, the effect of the Coulomb effect can be reduced, thus the writing accuracy can be improved. As shown in FIG. 7 and FIG. 9, the number of irradiation steps included in one shot and the total irradiation time of the irradiation steps do not change, the shot cycle and the writing time do not increase. In other words, the average value of the total current of the on-beam in the multi-beams in the shot cycle can be decreased without increasing the writing time.

FIG. 12A to FIG. 12C illustrate an example of grouping the multi-beams into groups A to C. For the purpose of illustration, FIG. 12A to FIG. 12C show an 8×8 beam array. It is preferable to perform grouping to prevent deviation of on-beam beam current. Therefore, rather than the grouping illustrated in FIG. 12C, grouping is preferably performed so that the beams in groups A to C are arranged in order as illustrated in FIG. 12A, FIG. 12B. In FIG. 12A, the beams adjacent to each other in x direction and y direction belong to different groups. In FIG. 12B, the beams adjacent to each other in x direction belong to different groups.

Next, the pattern writing method according to this embodiment will be described along the flowchart illustrated in FIG. 13. In a pattern area density calculation process (step S1), the area density calculator 111 virtually divides a writing region of the substrate 101 into a plurality of mesh regions. The size of each mesh region is approximately the same as the size of each beam included in the multi-beams, and each mesh region serves as a pixel (unit irradiation region). The area density calculator 111 reads writing data from the storage 140, and calculates the pattern area density ρ of each pixel using the pattern defined in the writing data.

In an irradiation time calculation process (step S2), the irradiation time calculator 112 multiplies the pattern area density ρ by a reference irradiation amount D₀ and a correction factor for correcting the proximity effect to calculate the irradiation amount of beam emitted to each pixel. The irradiation time calculator 112 calculates the irradiation time by dividing the irradiation amount by the current density.

In an irradiation time control data generation process (step S3), the data processor 113 takes the order of assignment of the irradiation steps into consideration, and distributes the irradiation time to multiple irradiation steps to generate irradiation time control data. For example, the data processor 113 divides the irradiation time by the quantization unit to calculate gradation value t (an irradiation time expressed as an integer). In the case of the example illustrated in FIG. 9, for the numerical sequence Tₖ (2⁵, 2₅, 2₅, 2₄, 2³, 2², 2¹, 2⁰), the data processor 113 determines, as the irradiation time control data, sequence bₖ (k=1, 2, . . . , 7) of ON/OFF flag corresponding to Tₖ.

The upper significant bits b₁, b₂, b₃ are determined from the value of m=FLOOR (t/T_{M}) obtained from corresponding times T_{M}=T₁=T₂=T₃=2⁵, and the order of assignment of the irradiation steps for each group, where m is a number not exceeding 3. The lower significant bits b₄, b₅, b₆, b₇, b₈ are determined by converting an integer value t−m×T_{M} to a binary. In more general, even when part of the numerical sequence Tₖ is not power of 2, the irradiation amount control data bₖ can be determined using the following Expression.

$${b}_{k} = floor ( \frac{t - {\sum }_{j = 1}^{k - 1} {b}_{j} {T}_{j}}{{T}_{k}} )$$

If the quantization unit Δ of the irradiation time is defined so that the irradiation time is shorter than the total value of the irradiation times of the irradiation steps, bit sequence bk is determined from the gradation value t of the irradiation time.

In a data transfer process (step S4), the writing controller 114 outputs irradiation time control data to the deflection control circuit 130. The deflection control circuit 130 outputs the irradiation time control data to the blanking aperture array substrate 204. The I/O circuit 31 of the blanking aperture array substrate 204 transfers the irradiation time control data to a corresponding individual blanking mechanism 40.

In the individual blanking mechanism 40, the irradiation time control data is transferred to the subsequent stage buffer one bit by one bit in accordance with a clock signal. The data corresponding to the irradiation time of each irradiation step is transferred, and ON/OFF of the beam is switched in each irradiation step in accordance with the irradiation time control data stored in the final stage buffer 44. When one irradiation is carried out in an irradiation step, the irradiation time control data for the next irradiation step is transferred to each buffer and the final stage buffer 44. In this manner, for each irradiation step, ON/OFF of each beam is switched in accordance with the irradiation time control data for each beam in each irradiation step.

In a writing process (step S5), the writing controller 114 controls the writer 150 to execute a writing process. The writing controller 114 controls the deflector 208 using the deflection control circuit 130 so as to irradiate each pixel corresponding to the transferred data with each beam in corresponding multi-beams, and performs positioning of the multi-beams. After completion of the positioning, the writing controller performs an irradiation process using the deflection control circuit 130, and performs blanking control so that each beam in the multi-beams performs irradiation with a predetermined irradiation amount of a corresponding pixel. When the irradiation process constituting one shot is completed, the data transfer process and the writing process are performed, and the next set of pixels are irradiated with.

In this manner, by repeating the processes in FIG. 13, the writer 150 uses the multi-beams to perform a writing operation for writing on a writing region by a raster scan method.

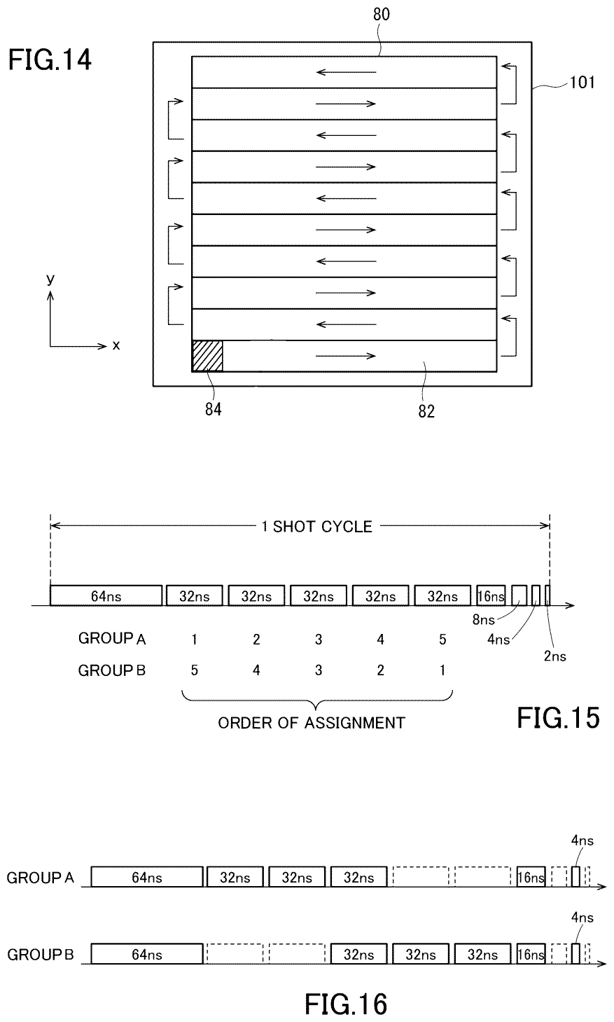

FIG. 14 is a conceptual diagram for explaining the writing operation. As illustrated in FIG. 14, a writing region 80 of the substrate 101 is virtually divided into e.g., a plurality of stripe regions 82 in rectangular form with a predetermined width in the y direction (the first direction). First, the XY stage 105 is moved, and adjustment is made so that an irradiation region 84 which can be irradiated with single irradiation of the multi-beams is located at the left end of the first stripe region 82, and writing is started.

When the first stripe region 82 is written, the XY stage 105 is moved in −x direction, thus writing proceeds relatively in +x direction. In writing, the multi-beams are deflected at least in Y direction by a deflector, thus the pixel to be exposed by the multi-beams is switched. Switching of an exposed pixel, and an exposure operation are repeated, thus all pixels defined in the stripe region 82 are exposed by the multi-beams. The XY stage 105 is continuously moved at a predetermined speed. The stage speed is set in a range in which the above-described writing operation is possible. After writing on the first stripe region 82 is finished, the stage position is moved in −y direction, and adjustment is made so that a beam array 84 is located at the right end of the second stripe region 82. Subsequently, the XY stage 105 is moved in +x direction, thus writing is performed in −x direction.

On the third stripe region 82, writing is performed in +x direction, and on the fourth stripe region 82, writing is performed in −x direction. The writing time can be reduced by performing writing while alternately changing the direction. Writing may be performed on each stripe region 82 in the same direction.

In this embodiment, multiple irradiation steps with the same irradiation time are provided in one shot cycle without changing the number of irradiation steps, the multi-beams are classified into multiple groups, and the order of assignment of the irradiation steps is changed between the groups. Thus, in at least part of the irradiation steps in one shot cycle, the timing when the beam is controlled ON is shifted between multiple groups of the multi-beams, thus the total current of averaged on-beam in the shot cycle can be reduced, the effect of the Coulomb effect can be reduced, and the writing accuracy can be improved.

In this embodiment, the number of groups when the multi-beams are grouped may be set to 2 instead of 3 in FIG. 9. In this case, group A and group B are set, for the beam in group A, the order of assignment of the first irradiation step is 1st, the order of assignment of the second irradiation step is 2nd, and the order of assignment of the third irradiation step is 3rd, and for the beam in group B, the order of assignment of the third irradiation step is 1st, the order of assignment of the first irradiation step is 2nd, and the order of assignment of the second irradiation step is 3rd. In the case of irradiation time for which one or two of the first, second, third irradiation steps are used, timing of part of the irradiation steps of group A and group B is controlled to be shifted.

The number of bits in the irradiation time control data may be increased, and the number of irradiation steps with the same irradiation time is increased so that the ON timing of the beam may be shifted efficiently.

In this embodiment, for example, as illustrated in FIG. 15, the number of digits (the number of bits) of the irradiation time control data is increased to 10 digits from 8 digits in FIG. 7, the quantization unit Δ is set to 2 ns, the first irradiation step is irradiation for 64 ns, and the second to sixth irradiation steps are irradiation for 32 ns. The seventh irradiation step is irradiation for 16 ns. The eighth irradiation step is irradiation for 8 ns. The ninth irradiation step is irradiation for 4 ns. The tenth irradiation step is irradiation for 2 ns. These 10 irradiation steps correspond to the irradiation steps obtained by dividing the first irradiation step with an irradiation time of 128 ns in the eight irradiation steps in FIG. 7 into four irradiation steps with an irradiation time of 32 ns. Therefore, the total value of the irradiation times in the irradiation steps in FIG. 15 is 255 ns which is the same as in FIG. 7. However, the number of writing steps increases, and the volume of irradiation time data to be transferred to the blanking aperture during writing increases, thus an overhead time for writing, such as a data transfer time, increases, and the writing time becomes longer than that when the irradiation time control data is eight digits.

In this embodiment, the multi-beams are classified into two groups A, B, and the order of assignment of the second to sixth irradiation steps is changed between group A and group B. For example, for the beam in group A, the order of assignment of the second irradiation step is 1st, the order of assignment of the third irradiation step is 2nd, the order of assignment of the fourth irradiation step is 3rd, the order of assignment of the fifth irradiation step is 4th, and the order of assignment of the sixth irradiation step is 5th. For the beam in group B, the order of assignment of the sixth irradiation step is 1st, the order of assignment of the fifth irradiation step is 2nd, the order of assignment of the fourth irradiation step is 3rd, the order of assignment of the third irradiation step is 4th, and the order of assignment of the second irradiation step is 5th.

For example, when the irradiation time for one shot is 180 ns, in one shot cycle, the beam is set ON in an irradiation step with an irradiation time of 64 ns, in three irradiation steps with an irradiation time of 32 ns, in an irradiation step with an irradiation time of 16 ns, and in an irradiation step with an irradiation time of 4 ns.

When the order of assignment of irradiation steps as described above is set, as illustrated in FIG. 16, the beam in group A is set ON in the first to fourth irradiation steps, in the seventh irradiation step, and in the ninth irradiation step. The beam in group B is set ON in the first irradiation step, in the fourth to seventh irradiation steps, and in the ninth irradiation step. Regarding the irradiation steps with an irradiation time of 32 ns, the beam in groups A, B is set simultaneously ON only once, and other than this, is set ON at a different timing, thus the amount of current of on-beam can be reduced. In this example, the number of groups when the multi-beams are grouped is set to 2, but may be set to 3. For example, group C is added to groups A, B of FIG. 15, and for the beam in group C, the following order of assignment may be made: the order of assignment of the second irradiation step is 4th, the order of assignment of the third irradiation step is 5th, the order of assignment of the fourth irradiation step is 1st, the order of assignment of the fifth irradiation step is 2nd, and the order of assignment of the sixth irradiation step is 3rd.

The number of bits in the irradiation time control data may be increased, and the shot cycle may be extended so that the ON timing of the beam may be shifted further efficiently.

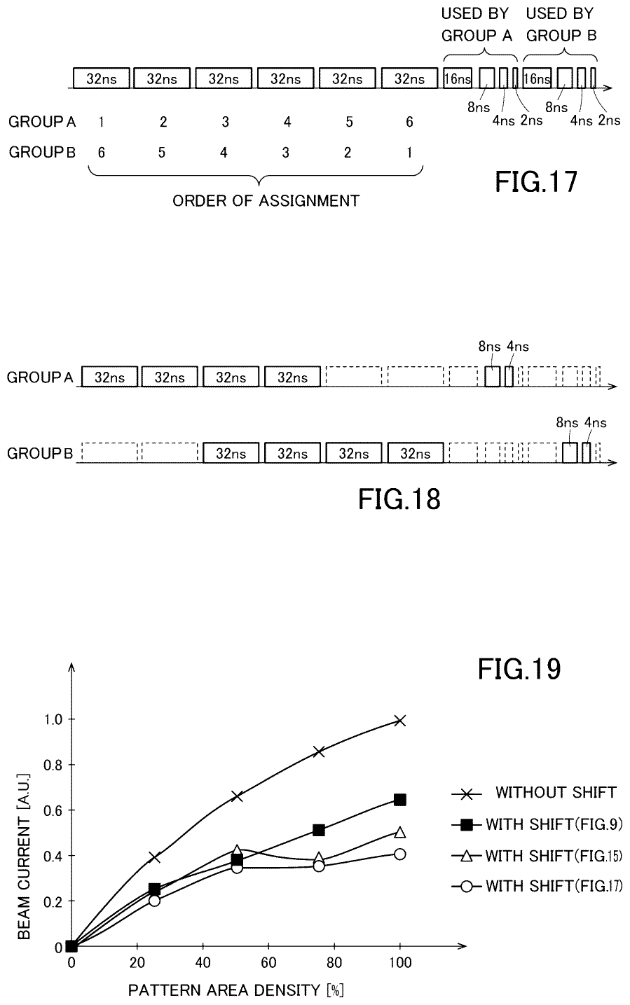

For example, as illustrated in FIG. 17, the number of digits (the number of bits) of the irradiation time control data is set to 14, the quantization unit Δ is set to 2 ns, and the first to sixth irradiation steps are irradiation for 32 ns. The seventh and eleventh irradiation steps are irradiation for 16 ns. The eighth and twelfth irradiation steps are irradiation for 8 ns. The ninth and thirteenth irradiation steps are irradiation for 4 ns. The tenth and fourteenth irradiation steps are irradiation for 2 ns. In other words, two sets of four irradiation steps with irradiation times of 16 ns, 8 ns, 4 ns, 2 ns are provided. Therefore, the total value of the irradiation times in the irradiation steps increases from 255 ns in FIG. 7 by 14 ns. That is, the shot cycle increases by 14 ns, thus the writing time extends.

The multi-beams are classified into two groups A, B, and the order of assignment of the first to sixth irradiation steps is changed between group A and group B. For example, for the beam in group A, the order of assignment of the first irradiation step is 1st, the order of assignment of the second irradiation step is 2nd, the order of assignment of the third irradiation step is 3rd, the order of assignment of the fourth irradiation step is 4th, the order of assignment of the fifth irradiation step is 5th, and the order of assignment of the sixth irradiation step is 6th. For the beam in group B, the order of assignment of the sixth irradiation step is 1st, the order of assignment of the fifth irradiation step is 2nd, the order of assignment of the fourth irradiation step is 3rd, the order of assignment of the third irradiation step is 4th, the order of assignment of the second irradiation step is 5th, and the order of assignment of the first irradiation step is 6th.

In addition, the set of the seventh to tenth irradiation steps is used only by group A, and the set of the eleventh to fourteenth irradiation steps is used only by group B.

For example, when the irradiation time for one shot is 140 ns, in one shot cycle, the beam is set ON in four irradiation steps with an irradiation time of 32 ns, in an irradiation step with an irradiation time of 8 ns, and in an irradiation step with an irradiation time of 4 ns.

When the order of assignment of irradiation steps as described above is set, as illustrated in FIG. 18, the beam in group A is set ON in the first to fourth irradiation steps, in the eighth irradiation step, and in the ninth irradiation step. The beam in group B is set ON in the third to sixth irradiation steps, in the twelfth irradiation step, and in the thirteenth irradiation step.

Regarding the irradiation steps with an irradiation time of 32 ns, the beam in groups A, B is set simultaneously ON only twice, and other than this, is set ON at a different timing, thus the average value of the total current of the on-beam in the shot cycle can be reduced. As seen from FIG. 16 and FIG. 18, in the irradiation steps of FIG. 18, for each of groups A, B, a set of irradiation steps with a short irradiation time is provided, thus the time during which the beam in group A and the beam in group B are set simultaneously ON can be reduced more efficiently than in the irradiation step in FIG. 16.

The average value of all current of the on-beam in the shot cycle is illustrated in FIG. 19 when shifting the ON timing of the beam is performed as illustrated in FIG. 9, FIG. 15, FIG. 17, and when shifting the ON timing is not performed. It has been confirmed that the average value of all current of the on-beam in the shot cycle is reduced by shifting the ON timing of the beam.

Also, it has been confirmed that the reduction amount of the average value of all current of the on-beam in the shot cycle increases for a higher pattern area density. This is because with a higher pattern area density, the irradiation amount decreases due to the proximity effect correction, and in one shot cycle, the number of irradiation steps in which the beam is set OFF increases, thus shifting of the ON timing of the beam can be efficiently performed between irradiation steps.

In the above embodiment, shaping of the beam and blanking control may be performed by the openings of the blanking aperture array substrate, and the shaping aperture array member may be omitted.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A multi-charged particle beam writing method comprising:
a process of emitting multi-beam of a charged particle;
a process of grouping a plurality of beams included in the multi-beam into a plurality of beam groups;
a process of determining an irradiation time for each beam in each shot of the multi-beam from writing pattern data;
a shot division process for dividing the shot into a plurality of irradiation steps including irradiation steps with different irradiation times, grouping, as a first group, a plurality of irradiation steps, which are part of the divided plurality of irradiation steps, and have a predetermined first irradiation time, and selecting a set of irradiation steps for which a total of irradiation times of the irradiation steps is a determined irradiation time for the beam; and
a process of making a shot of the multi-beam by switching between ON/OFF for each beam in the multi-beam and performing the set of the plurality of irradiation steps,
wherein in the shot division process, timing of the irradiation steps in the first group of the plurality of irradiation steps belonging to each of the plurality of beam groups is determined based on a predetermined order of assignment to be different for each of the beam groups, and a number of the irradiation steps which are to be set ON.

2. The multi-charged particle beam writing method according to claim 1,
wherein the plurality of irradiation steps include the first group, and a second group of irradiation steps constituted by irradiation steps having an irradiation time shorter than the first irradiation time.

3. The multi-charged particle beam writing method according to claim 2,
wherein the first irradiation time is a longest irradiation time among irradiation times of the plurality of irradiation steps.

4. The multi-charged particle beam writing method according to claim 1,
wherein an irradiation time of each of the plurality of irradiation steps is defined to be proportional to power of 2.

5. The multi-charged particle beam writing method according to claim 2,
wherein in the second group, beam-on timing of a plurality of irradiation steps with a second irradiation time varies with each of the beam groups.

6. The multi-charged particle beam writing method according to claim 1,
wherein in the multi-beam, adjacent beams in a writing proceed direction or a direction linearly independent from the writing proceed direction are classified into different groups.

7. A multi-charged particle beam writing apparatus comprising:
an emitter configured to emit multi-beam of a charged particle; and
a writing controller configured to switch between ON/OFF for each beam in the multi-beam, and control an irradiation time for the beam in each shot of the multi-beam, the irradiation time being determined from writing pattern data,
wherein the writing controller groups a plurality of beams included in the multi-beam into a plurality of beam groups, divides the shot into a plurality of irradiation steps including irradiation steps with different irradiation times, groups, as a first group, a plurality of irradiation steps, which are part of the divided plurality of irradiation steps, and have a predetermined first irradiation time, and selects a set of irradiation steps for which a total of irradiation times of the irradiation steps is a determined irradiation time for the beam, and determines timing of the irradiation steps in the first group of the plurality of irradiation steps belonging to each of the plurality of beam groups based on a predetermined order of assignment to be different for each of the beam groups, and a number of the irradiation steps which are to be set ON.

8. The multi-charged particle beam writing apparatus according to claim 7,
wherein the plurality of irradiation steps include the first group, and a second group of irradiation steps constituted by irradiation steps having an irradiation time shorter than the first irradiation time.

9. The multi-charged particle beam writing apparatus according to claim 8,
wherein the first irradiation time is a longest irradiation time among irradiation times of the plurality of irradiation steps.

10. The multi-charged particle beam writing apparatus according to claim 7,
wherein an irradiation time of each of the plurality of irradiation steps is defined to be proportional to power of 2.

11. The multi-charged particle beam writing apparatus according to claim 8,
wherein in the second group, beam-on timing of a plurality of irradiation steps with a second irradiation time varies with each of the beam groups.

12. The multi-charged particle beam writing apparatus according to claim 7,
wherein in the multi-beam, adjacent beams in a writing proceed direction or a direction linearly independent from the writing proceed direction are classified into different groups.
